(19) United States
(12) Patent Application Publication
(10) Pub. No.: US 2012/0273935 A1
(43) Pub. Date: Nov. 1, 2012

(54) Semiconductor Device and Method of Making a Semiconductor Device

(76) Inventors: Stefan Martens, Muenchen (DE); Tze Yang Hin, Penang (MY); Kian Pin Queck, Malacca City (MY); Kathleen Ong, Mclaka (MY); Chin Wei Ronnie Tan, Pulau Pinang (MY); Beng Keh See, Bukit Katil (MY); Ulrich Krumbein, Rosenheim (DE); Horst Theuss, Wenzenbach (DE)

(21) Appl. No.: 13/097,851

(22) Filed: Apr. 29, 2011

(51) Int. Cl. H01L 23/498; H01L 21/50; H01L 21/78

(52) U.S. Cl. 257/737; 438/113; 438/123; 438/125; 257/E21.599; 257/E23.068; 257/E21.499

(57) ABSTRACT

A semiconductor device and a method of manufacturing a semiconductor device are disclosed. An embodiment comprises forming a bump on a die, the bump having a solder top, melting the solder top by pressing the solder top directly on a contact pad of a support substrate, and forming a contact between the die and the support substrate.

### TECHNICAL FIELD

The present invention relates generally to packaged electronic components and methods for packaging electronic components.

### BACKGROUND

Electronic component packaging generally is the final stage of semiconductor device fabrication. The electronic components may be incorporated into an individual protective package, mounted with other components in hybrid or multi-component modules or connected directly onto a printed circuit board (PCB).

### SUMMARY OF THE INVENTION

In accordance with an embodiment of the present invention, a method of forming a semiconductor device is disclosed. The method comprises forming a bump on a die, the bump having a solder top, melting the solder top by pressing the solder top directly on a contact pad of a support substrate, and forming a contact between the die and the support substrate.

In accordance with another embodiment of the present invention, an interconnect is disclosed. The interconnect comprises a chip pad arranged on a chip and a contact pad arranged on a support structure. The interconnect further comprises a pillar bump, the pillar bump formed on the chip pad and a contact, the contact connecting the pillar bump to the contact pad, the contact comprising a first alloy and a second alloy, the first alloy being different than the second alloy.

In accordance with yet another embodiment of the present invention, a method of manufacturing a semiconductor device is disclosed. The method comprises forming bump on a wafer and singulating the wafer, forming a plurality of dies, each die having a bump. The method further comprises placing a tape on the bumps, flipping the wafer and attaching the bump of one of the dies to a support substrate.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a conventional contact;

FIG. 2 shows an embodiment contact;

FIG. 3 shows bond contacts on a wafer;

FIG. 4a shows a wafer on a first tape;

FIG. 4b shows a second tape attached to the bond contacts of the wafer;

FIG. 4c shows a flipped wafer with a removed first tape;

FIG. 5a shows placing a die to a support substrate;

FIG. 5b shows bonding;

FIG. 6a shows an embodiment of a contact;

FIG. 6b shows an embodiment of a contact; and

FIG. 7 an embodiment of a packaged semiconductor device.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The present invention will be described with respect to embodiments in a specific context, namely a method of manufacturing semiconductor devices. The specific embodiments discussed are merely illustrative of specific ways to make and use the invention, and do not limit the scope of the invention.

Flip chip assembly was introduced around 50 years ago and is a well established technology. Flip chip assembly has not changed much since. Flip chip assembly is performed by flip chip bonders applying a two arm concept. Singulated dies are placed on a sawing frame with upward facing flip chip bumps. The first handling arm of the flip chip bonder picks and flips the die. Then, the second handling arm takes over and dips the flip chip bumps into a container containing flux. The second handling arm places the die onto a leadframe at ambient temperature and the die attaches to the leadframe due to the flux. Flux dissolves oxides on metal surfaces and acts as an oxygen barrier by coating the surfaces, preventing their oxidation. A contact between the die and the leadframe is not yet formed. The leadframe with the attached die is then transferred into a reflow oven. The reflow oven heats the collapsible flip chip bumps above a melting temperature and a connection between the leadframe and the chip is formed. The flux must be removed before the space between the leadframe and the chip is filled with a molding compound.

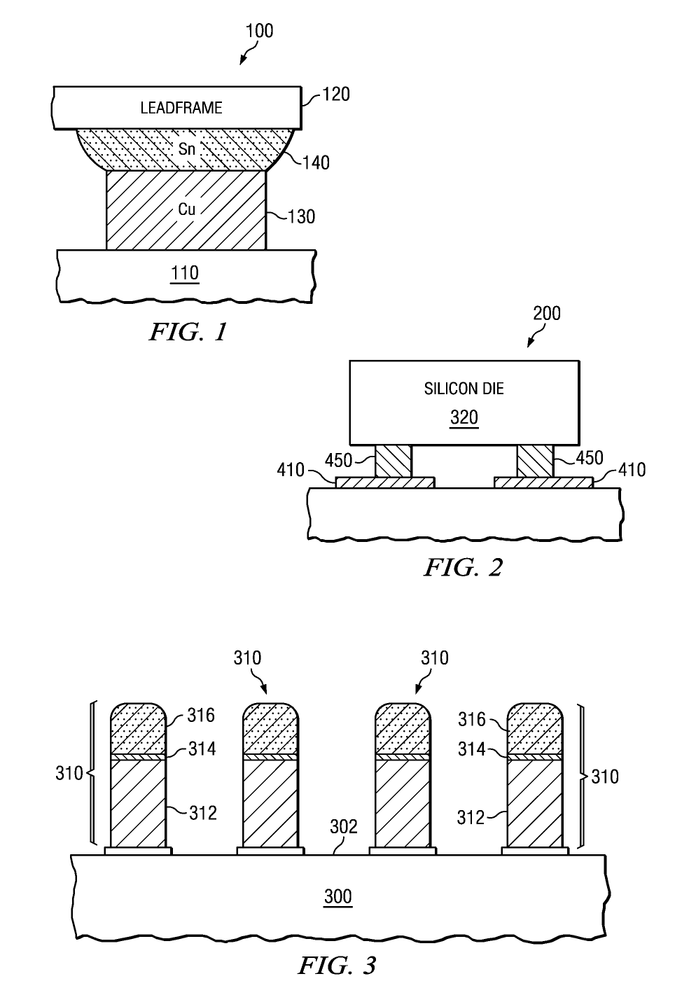

FIG. 1 shows a conventional interconnect 100 between a chip 110 and a leadframe 120. As can be seen from FIG. 1 the copper pillar 130 is connected to the leadframe 120 by a solder contact 140 consisting essentially of tin (Sn). The conventional interconnect 100 is formed by the flip chip assembly process described in the previous paragraph.

Diffusion bonding is a process to assemble dies with a conductive metal backside onto leadframes. A die-bonder picks the dies from the sawing frame with the active side facing upward and the metal backside facing downward. The whole backside of the die is placed on a heated leadframe thereby bonding with the leadframe.

Embodiments of the present invention provide a bump contact. The bump contact may be a copper (Cu) pillar bump. The bump contact may comprise binary or ternary alloy. The bump contact may comprise a layer stack of binary and/or ternary alloys. The solder material may be essentially consumed and transformed into these alloys.

Embodiments of the present invention provide a method for manufacturing an interconnect between a chip and a support substrate. A bump contact connected to the chip may be placed on the heated support substrate. A top portion of the bump contact melts and may form binary and/or ternary alloys. The melted top portion of the bump contact forms a reliable contact between the chip and the support substrate.

Embodiments of the present invention provide a method for manufacturing a semiconductor device. A wafer may be placed on a first foil with bump contacts facing up. A second foil may be placed on the bump contacts. The wafer may be flipped so that the bump contacts face downward and the first foil may be removed. A cut die of the wafer may be placed on a support substrate with the bump contacts facing downward. The die may be placed on the support substrate in a one die-bonder arm movement.

Embodiments of the present invention comprise several advantages over conventional processes. The speed to place the dice onto the support substrate may be increased from around 2500 units per hour (UPH) to more than about 6000 UPH. Moreover, a height of a formed contact between a support substrate and a die may be reduced relative to conventional devices. For example, the height of the interconnect may be about 55 μm to about 65 μm. Advantageously, the electrical path between the substrate and the die may be shorter than in conventional devices

FIG. 2 shows an embodiment of a semiconductor device 200. The semiconductor device comprises a chip 320 and contact pads 410 of a support substrate. The chip 320 is connected to the contact pads 410 via interconnects 450. The interconnects 450 may comprise a bump and at least one layer of binary or ternary alloys. The semiconductor device 200 may be manufactured according to the manufacturing process described in the following paragraphs.

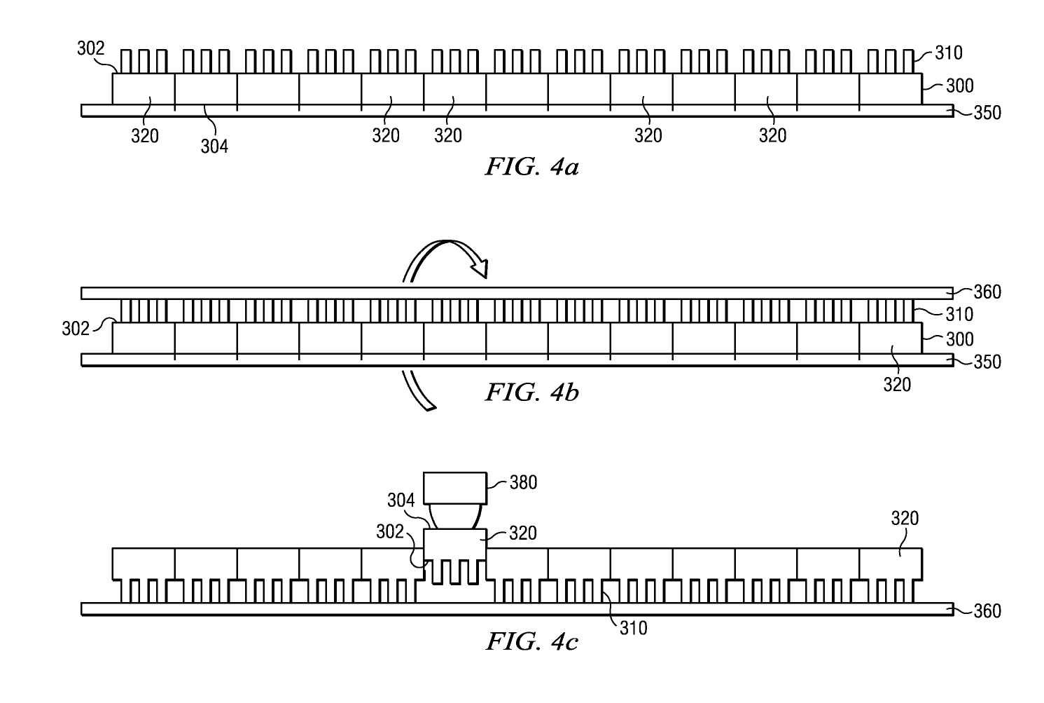

FIG. 3 shows bumps 310 on a wafer 300. The bumps 310 may be formed on a first side 302 of the wafer 300. The first side 302 is opposite to a second side 304 (shown in FIG. 4a) of the wafer. The first side 302 may be an active side and the second side 304 may be a back side of wafer or vice versa. Alternatively, the bumps 310 may be made on any side of the wafer 300. A bump 310 may comprise a conductive pillar 312. The conductive pillar 312 may be copper (Cu), gold (Au) or the like. The bump 310 may further comprise an optional intermediate layer 314. The optional intermediate layer 314 may be disposed over the conductive pillar 312 and may comprise a conductive material such as nickel (Ni), palladium (Pd), tantalum nitride (TaN) or the like. The bump 310 may further comprise a top layer or a solder top 316. The top layer 316 may be formed over the optional intermediate layer 314. The top layer 316 may be round or may or may comrpise angles. The bumps 310 may comprise other forms than a pillar form.

The top layer 316 may comprise a reflowable solder. The reflowable solder may be a lead based or a lead free material. The reflowable solder may comprise metals such as tin (Sn), lead (Pb), antimony (Sb), bismuth (Bi), silver (Ag), copper (Cu) or combinations thereof. In one embodiment the reflowable solder consists essentially of tin (Sn) or silver/tin (SnAg).

The bump 310 may be formed by forming a photoresist over the wafer 300. Openings may be formed in the photoresist and the openings may be used to form the contact pillars 312, the optional intermediate layer 314 and the top layer 316 of the bump 310. After forming the bump 310, the remaining portion of the photoresist is removed. Free standing bumps 310 may remain over the wafer 300 as is shown in FIG. 3. The bumps 310 may be arranged such that each die or chip to be singulated from the wafer 300 comprises at least one bump 310.

After forming the bumps 310 on the wafer 300, the wafer 300 may be cut. Cutting the wafer 300 may be carried out by placing the wafer 300 on a first foil or a dicing tape 350 as shown in FIG. 4a. A dicing tape 350 can be a flexible plastic film made of PVC, polyolefin, or polyethylene backing material with an adhesive to hold the dies in place. The dicing tape 350 is available in a variety of thicknesses, from about 75 μm to about 350 μm, with a variety of adhesive strengths, designed for various chip sizes and materials. The dicing tape 350 may be a UV tape in which the adhesive bond is broken or reduced by exposure to UV light after dicing, keeping the adhesive strong during cutting while allowing a clean and easy removal after cutting. In another example the bond is broken by a thermal treatment. The dicing tape 350 may hold the die in place after the cutting operation. The wafer 300 is cut by mechanical sawing or by laser cutting or plasma dicing. The cut wafer 300 forming dice 320 on a dicing tape 350 is shown in FIG. 4a.

After cutting the wafer 300 into dice 320, a second foil 360 may be placed on the whole wafer 300. The second foil 360 may be placed on the bumps 310 of the active side 302 of the wafer 300. FIG. 4b shows the wafer 300 arranged between the two foils 350, 360 with the bumps 310 facing upward. Then, the wafer 300 may be flipped so that the bond contacts 310 and the active side 302 may face downward. The wafer 300 may be flipped manually, automatically or a combination of both of them. In one embodiment the wafer 300 may be flipped first and then bonded to the second foil 360.

The dicing tape 350 may then be removed from the wafer 300 by peeling, for example. The second foil 360 may be attached to the bond contacts 310 with a stronger adhesive strength than the first foil 350 to the back side 304 of the dice 320 of the wafer 300. Accordingly, the chips 320 may stick to the second foil 360 while the first foil 350 is peeled off. In one embodiment the first foil 350 and the second foil 360 are different type of foils. For example, one foil may be a regular dicing tape and the other foil may be an UV tape.

In one embodiment the dicing tape 350 may be removed before the wafer 300 is flipped.

In a mechanical operation, a die-bonder 380 as shown in FIG. 4c may pick up the dies 320 from the second foil 360. With the active side 302 down and the back side 304 up the die-bonder 380 may move the die 320 in a fast operation from the wafer 300 to a support substrate. FIG. 4c shows how a die 320 is removed from the wafer/second foil 300/360 by a die-bonder 380. Flipping the wafer 300 and moving the dies 320 with downward facing chips 320 may enable the die-bonder 380 to process more than about 6000 units per hour (UPH) compared to about 2500 units per hour (UPH) in conventional applications.

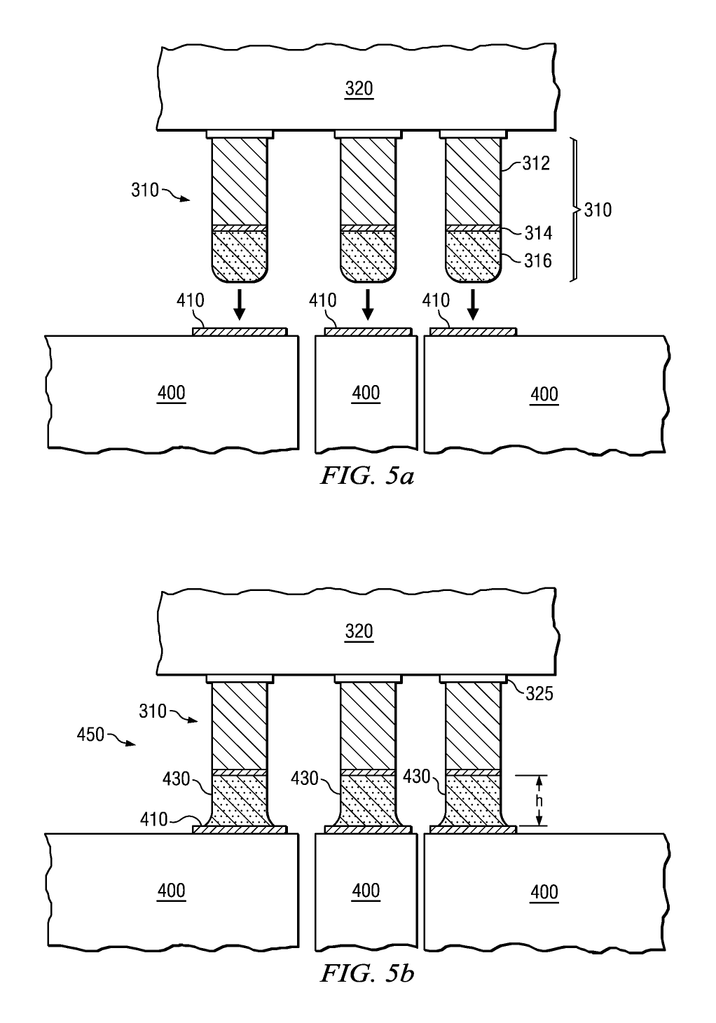

FIG. 5a shows a die 320 with three bumps 310 shortly before the bumps 310 are placed on contact pads 410 of a support substrate 400. The support substrate 400 may be a leadframe, a glass-core based substrate, or a printed circuit board (PCB), for example. The contact pads 410 and/or the support substrate 400 may comprise a conductive material such as nickel (Ni) or copper (Cu). The contact pads 410 and/or the support substrate 400 may be plated with silver (Ag) or gold (Au) in some embodiments and may be plated with a metal layer stack such as palladium/gold (Pd/Au) in other embodiments.

The bumps 310 may be placed on a heated support substrate 400. The support substrate 400 and the contact pads 410 may be heated to a temperature of about 180 C to about 350 C. The die 320 and the bumps 310 may be pressed onto the contact pads 410 by applying a bonding pressure for a certain amount of time. The bonding pressure may be about 5 g/mm² to about 500 g/mm². The bonding time may be between about 10 ms and about 1 s depending on the die size.

Upon pressing the bond contacts 310 onto the heated contact pads 410, the top layer 316 of the bond contact 310 may melt and the conductive pillar 312 material and/or the conductive material of the support substrate 400 or the contact pad 410 may diffuse into the melting top layer 316. The melting and the diffusion of the materials may start immediately upon applying the bonding pressure. The top layer 316 may transform itself to a contact 430 as shown in FIG. 5b. Binary or ternary alloys may be formed in the contact 430. The binary or ternary alloys may have a higher melting temperature than the material of the top layer 316. Therefore, the binary or ternary alloys may solidify and may form a stable and reliable contact 430 between the conductive pillars 312 and the contact pads 410. The diffusion of the conductive pillar 312 material and the support substrate/contact pad 400/410 material may be controlled by parameters such as support substrate temperature, bonding pressure and bonding time. The process may take place without any application or use of flux.

For example, a height of the interconnect 450 may be about 55 μm to about 65 μm including a height of the contact 430 of about 3 μm to about 10 μm.

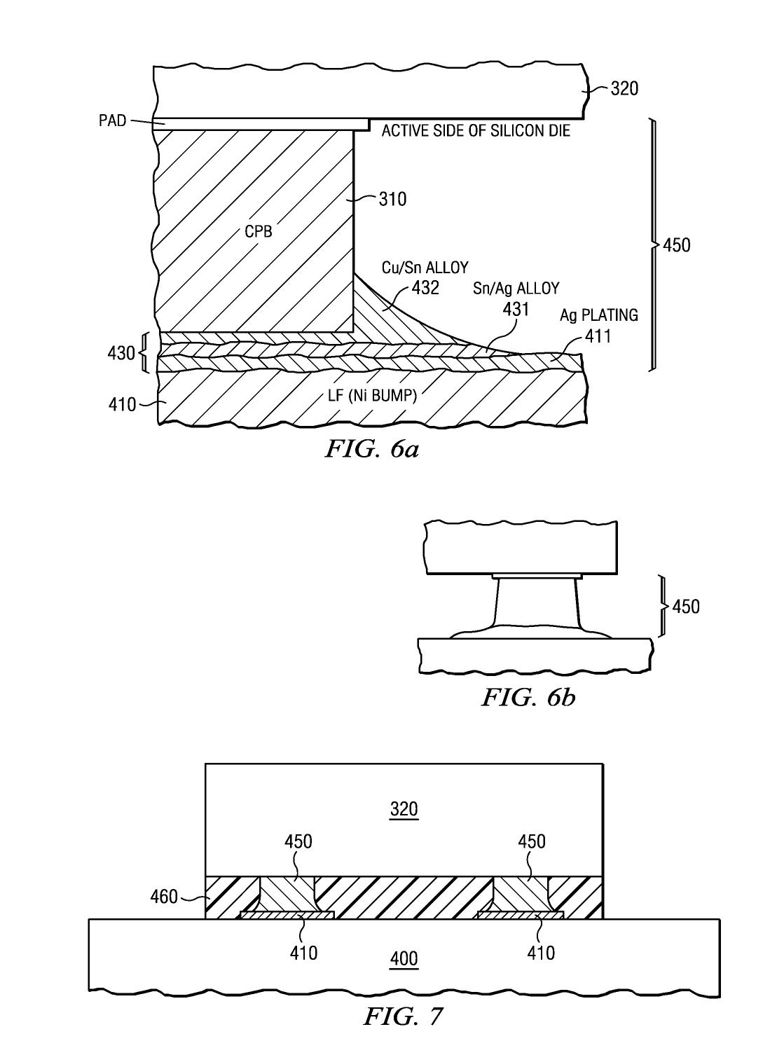

FIG. 6a shows one embodiment of an interconnect 450. The interconnect 450 is formed with the bump 310 of FIG. 3 (but without the optional intermediate layer 314). The conductive pillar 312 is a copper pillar. The melting solder top 316, together with other chemical elements, forms the contact 430. The contact pad 410 is nickel (Ni) plated with silver (Ag). The contact 430 is formed by pressing the bump 310 on the contact pad 410. Silver (Ag) from the silver (Ag) plating and copper from the conductive pillar 312 diffuses into the melting solder top 316 forming alloys. A binary tin/silver (Sn/Ag) alloy layer 431 is formed near the contact pad 410 above the plated silver (Ag) 411. A binary copper/tin (Cu/Sn) alloy layer 432 is formed below or around the tip of the copper pillar 312 and above the binary tin/silver (Sn/Ag) alloy layer 431. In one embodiment a ternary a copper/tin/silver (Cu/Sn/Ag) alloy layer (not shown) may be formed between the binary tin/silver (Sn/Ag) alloy layer 431 and the binary copper/tin (Cu/Sn) alloy layer 432.

The silver plating layer 411 may be about 1 μm to about 4 μm thick, the silver/tin (Ag/Sn) alloy layer 431 may be about 4 μm to about 5 μm thick, and the copper/tin (Cu/Sn) alloy layer 432 may be about 4 μm to about 5 μm thick. The thickness of the alloy layers 431, 432 may be dependent on the temperature budget, e.g., the thickness of the alloy layers 431, 432 may increase if the heating time increases.

FIG. 6b shows another embodiment of a contact 430 of an interconnect 450. Again, the interconnect 450 is formed with the bump 310 of FIG. 3 (but without the optional intermediate layer 314). The conductive pillar 312 is a copper pillar. The contact pad 410 is nickel (Ni) plated with gold (Au). Gold (Au) from the gold (Au) plating 412 and copper (Cu) from the conductive pillar 312 may diffuse into the melting solder top 316 forming alloys. A binary tin/gold (Sn/Au) alloy layer may form near the contact pad 410 above the plated gold (Au) 412. A binary copper/tin (Cu/Sn) alloy layer may form below or around the tip of the copper pillar 312 and above the binary tin/gold (Sn/Au) alloy layer. In one embodiment a ternary a copper/tin/gold (Cu/Sn/Au) alloy layer may be formed between the binary tin/gold (Sn/Au) alloy layer and the binary copper/tin (Cu/Sn) alloy layer. The alloy layers are not individually shown in the interconnect 430. The tin gold (Sn/Au) alloy layer may be Au₅Sn or AuNiSn₂ if the gold (Au) plating is fully consumed and a phase with Ni of the support substrate is formed.

In another embodiment, the contact 430 comprises two copper/tin (Cu/Sn) alloy layers. The first binary copper/tin (Cu/Sn) alloy layer is formed near the contact pad 410 of the support substrate 400. A second binary copper/tin (Cu/Sn) alloy layer is formed below and around the tip of the copper pillar 312 above the first binary copper/tin (Cu/Sn) alloy layer. The first binary copper/tin (Cu/Sn) alloy layer is formed by copper (Cu) from a copper (Cu) pad 410 and/or a copper (Cu) leadframe diffusing into the melting solder top 316 of the bump 310.

FIG. 7 shows an embodiment of a packaged semiconductor device. After the interconnects 450 have been formed the space between the support substrate 400 and the chip 320 may be filled with a molding compound 460. The molding compound 460 may be an electrically insulating adhesive. For example, the electrically insulating adhesive may be an epoxy resin or an epoxy resin filled with silicon oxide filler. Advantageously, when flux is not used, the space between the support substrate 400/contact pad 410 and the chip 320 does not need to be cleaned of flux before it is filled with the molding compound 460. The avoidance of flux simplifies and speeds up the manufacturing process.

Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for manufacturing a semiconductor device, the method comprising:
forming a bump on a die, the bump having a solder top;
melting the solder top by pressing the solder top directly on a contact pad of a support substrate; and
forming a contact between the die and the support substrate.

2. The method according to claim 1, further comprising pressing the solder top on the contact pad at a temperature between about 180 C and 350 C.

3. The method according to claim 1, further comprising cutting a wafer into a plurality of dies, flipping the wafer, and selecting a die after forming the bump on the die.

4. The method according to claim 1, further comprising disposing a molding compound in a space between the support substrate and the die after forming the contact between the die and the support substrate.

5. The method according to claim 1, wherein the support substrate is a leadframe or a glass-core-based substrate.

6. The method according to claim 1, wherein the contact comprises a tin/silver (Sn/Ag) alloy and a copper/tin (Cu/Sn) alloy or a gold/tin (Au/Sn) alloy and a copper/tin (Cu/Sn) alloy.

7. The method according to claim 1, wherein the bump is a copper pillar bump.

8. The method according to claim 1, wherein a distance between the die and the support substrate is about 55 μm to about 65 μm.

9. An interconnect comprising:
a chip pad arranged on a chip;
a contact pad arranged on a support structure;
a pillar bump, the pillar bump disposed on the chip pad; and
a contact, the contact connecting the pillar bump to the contact pad, the contact comprising a first alloy and a second alloy.

10. The interconnect according to claim 9, wherein the pillar bump comprises copper (Cu), wherein the first alloy is copper/tin (Cu/Sn), and wherein the second alloy is tin/silver (Sn/Ag).

11. The interconnect according to claim 9, wherein the pillar bump comprises copper (Cu), wherein the first alloy is copper/tin (Cu/Sn), and wherein the second alloy is tin/gold (Sn/Au).

12. A method for manufacturing a semiconductor device, the method comprising:
forming bumps on a wafer;
singulating the wafer to form a plurality of dies, each die having a bump;
placing a tape on the bumps;
flipping the wafer;
attaching the bump of one of the dies to a support substrate.

13. The method according to claim 12, wherein attaching the bump of one of the dies to the support substrate comprises pressing the bump onto a heated support substrate.

14. The method according to claim 12, further comprising attaching a first side of the wafer to a sawing foil before singulating the wafer.

15. The method according to claim 12, wherein placing the tape on the bumps comprises attaching the bumps located on a second side of the wafer to the tape.

16. The method according to claim 14, further comprising removing the sawing foil from the wafer after flipping the wafer.

17. The method according to claim 12, wherein the tape is placed on the bumps after the wafer is flipped.

18. The method according to claim 12, further comprising picking the one of the dies with the bump facing downward.

19. The method according to claim 12, wherein the support substrate comprises a leadframe or a glass-core-based substrate.

20. The method according to claim 12, further comprising filling a space between the one of the dies and the support substrate with a molding compound.
